(19) United States
(12) Patent Application Publication
(10) Pub. No.: US 2007/0072000 A1
(43) Pub. Date: Mar. 29, 2007

(54) Organic electroluminescent element and manufacturing method thereof

(75) Inventors: Hiroyuki Mochizuki, Ikeda-shi (JP); Toshiko Mizokuro, Osaka (JP); Nobutaka Tanigaki, Osaka (JP); Takashi Hiraga, Ikeda-shi (JP); Norio Tanaka, Tokyo (JP)

Correspondence Address: OLIFF & BERRIDGE, PLC, P.O. BOX 19928, ALEXANDRIA, VA, 22320, US

(73) Assignees: NATIONAL INSTITUTE OF ADVANCED INDUSTRIAL SCIENCE AND TECHNOLOGY, Tokyo (JP); DAINICHISEIKA COLOR & CHEMICALS MFG. CO., LTD., Tokyo (JP)

(21) Appl. No.: 10/572,643

(22) PCT Filed: Oct. 14, 2004
(86) PCT No.: PCT/JP04/15564

§ 371 Date: Mar. 20, 2006

(30) Foreign Application Priority Data
Oct. 24, 2003 (JP) 2003-364219

(51) Int. Cl. B32B 19/00

(52) U.S. Cl. 428/690

(57) ABSTRACT

An organic electroluminescent element, which has a positive electrode 2 and a glass substrate 1 sequentially laminated on one side of a light-emitting layer 4 and a negative electrode 5 formed on the other side of the light-emitting layer 4, has a functional layer which is formed by causing gas molecules of at least one type of compound selected from the group consisting of dyes and charge transport materials to contact and penetrate a ƒÎ conjugated organic polymer compound.

### BACKGROUND OF THE INVENTION

1. Field of the Invention

The present invention relates to a bright and highly efficient electroluminescent element which has gas molecules of a low molecular compound having charge transport ability penetrated into a π conjugated organic polymer compound, and to a method of manufacturing such an element.

2. Description of the Invention

In recent years, a great deal of effort has been focused on developing electroluminescent elements using an organic compound for use in next-generation flat displays. There are published reports of an element having a double structure in which an organic fluorescent dye is used for a light-emitting layer and the light-emitting layer and an organic charge transport compound are laminated (e.g., Japanese Patent Laid-Open Publication No. SHO 59-194393), and an element which has a polymer used as a fluorescent material (e.g., PCT Application Publication No. WO9013148, Japanese Patent Laid-Open Publication No. HEI 3-244630). These electroluminescent elements using an organic fluorescent material can be driven with a low-voltage direct-current, and can easily emit light of multiple colors in addition to the high luminance. Especially, lamination of thin films formed of a low molecular compound by a vacuum deposition method can be used to configure a highly reliable full color device. However, a device configured by the above method has disadvantages in that costs are high and that it is difficult to form a device having a large area.

Accordingly, there is proposed an organic electroluminescent element (polymer type electroluminescent element) formed of a thin film which is produced by applying a conjugation type polymer with phenylenevinylene, thiophene, benzene or the like used as a basic skeleton. Apart from the organic electroluminescent element mainly using a low molecular organic compound, a polymer LED using a polymer light-emitting material is proposed in PCT Application Publication No. WO9013148, Japanese Patent Laid-Open Publication No. HEI 3-244630, Appl. Phys. Lett., Vol. 58, page 1982 (1991) and the like. PCT Application Publication No. WO9013148 discloses examples of producing a poly (p-phenylenevinylene) (PPV) thin film by forming a soluble precursor as a film on an electrode and thermally treating to convert into a conjugation type polymer and using the PPV for an element.

As to the manufacturing of an organic compound thin film, Japanese Patent Laid-Open Publication No. 2001-026884 describes that in order to uniformly penetrate and disperse an organic compound, which has an affinity for a resin and a sublimation property, to the surface of a molded product of the resin, the resin mold and the organic compound, which has an affinity for the resin and the sublimation property, are placed in an airtight container, and the container's inside pressure and temperature are adjusted to have the organic compound in a state of a saturated sublimation pressure, so that the organic compound vapor adheres uniformly to the surface of the resin mold and also penetrates and disperses into it.

Japanese Patent Laid-Open Publication No. 2001-003195 discloses a process for modification and/or coloring of a resin surface layer in order to modify and/or color the resin surface layer by uniformly penetrating and dispersing into the surface of a resin mold an organic compound which has an affinity for the resin and a sublimation property, wherein the resin mold and the organic compound having an affinity for the resin and the sublimation property are placed in an airtight container, and the inside pressure and temperature are adjusted to place the organic compound in a saturated sublimation pressure state to promote uniform adherence of organic compound vapor to the surface of the resin mold, as well as the organic compound's penetration into and dispersion throughout the resin mold.

Japanese Patent Laid-Open Publication No. 2000-281821 discloses a method for modifying a surface layer to obtain a functional thin film having uniform thickness and composition by modifying the surface layer composition of a target object to be coated by a sublimation material which interacts with it, wherein the sublimation material which interacts with the surface layer composition of the target object is placed in a closed space; the space is adjusted to a saturated sublimation pressure state of the sublimation material; the sublimation material vapor is adhered to the surface layer composition of the target object; and the adhered sublimation material is further penetrated and dispersed from the surface of the surface layer composition into the surface layer, thereby interacting with the surface layer composition.

However, materials such as the above-described unsubstituted π conjugated organic polymer compound have poor workability, including poor dopability. Electroluminescent elements produced using such materials have relatively poor luminance, and the luminescent color is limited to only the original color of fluorescence.

### SUMMARY OF THE INVENTION

The present invention advantageously improves luminance and a luminous efficiency by controlling the luminescent color of an organic electroluminescent element containing the π conjugated organic polymer compound.

To provide the above-described advantages, the present invention provides an organic electroluminescent element containing a π conjugated organic polymer compound, comprising a functional layer formed by causing gas molecules of at least one type of compound selected from the group consisting of dyes and charge transport materials to contact and penetrate the π conjugated organic polymer compound. The charge transport material of the present invention is a low molecular weight material and has a sublimation property. Besides, it is a material which provides a charge transport ability to its noncrystalline solid film or a dispersoid into a polymer matrix which is a dielectric substance (insulator). The material having the charge transport ability is classified into a hole transport material transporting a positive (+) charge and an electron transport material transporting a negative (−) charge. As the hole transport materials, there are low molecular compounds having a carbazole ring, a thiophene ring, triphenylamine, triphenylmethane or distilbene structure, and also compounds having such low molecular compounds bonded with a diazo or triazo group. As the electron transport material, there are compounds having an oxadiazole ring, a triazole ring, a quinone ring, an imidazole ring, a flavone ring, a thiazole ring, a benzimidazole ring, a quinoline ring, a quinozaline ring or a pyrazine ring and compounds having a nitro group or a cyano group introduced into such compounds. There is also an electron transport compound having a light emission ability, and also aluminum, zinc, beryllium, europium and erbium complexes having a benzooxadiazole ring, a quinolyl ring, a benzoquinolyl ring, a benzothiazole ring or a hydoxyflavone ring in a ligand.

And, another electroluminescent element of the present invention has a light-emitting layer and/or a charge transport layer as the functional layer.

Another electroluminescent element according to the present invention has the π conjugated organic polymer compound which has a chemical structure represented by a general formula —(Ar) n —and/or —(ArA)n, where Ar represents a benzene ring, a thiophene ring, a pyridine ring, a pyrrole ring or an oxadiazole ring, and A represents a double bond, a triple bond or an NH bond.

### BRIEF DESCRIPTION OF THE DRAWINGS

FIG. 1 is a sectional diagram of a polymer electroluminescent element according to an embodiment of the invention;

FIG. 2 is a sectional diagram showing an outline of a light guide fabrication apparatus in one stage (up to vacuum drawing) of the electroluminescent element fabrication method of Example 1;

FIG. 3 is a sectional diagram showing an outline of the light guide fabrication apparatus in one stage (up to sealing of a tube) of the electroluminescent element fabrication method of Example 1;

FIG. 4 is a sectional diagram showing an outline of the light guide fabrication apparatus in one stage (after sealing the tube) of the electroluminescent element fabrication method of Example 1;

FIG. 5 is a sectional diagram showing an outline of the light guide fabrication apparatus in one stage (when heating) of the electroluminescent element fabrication method of Example 1;

FIG. 6 is a sectional diagram showing an outline of a light guide fabrication apparatus in one stage (up to vacuum drawing) of the electroluminescent element fabrication method of Comparative Example 1;

FIG. 7 is a sectional diagram showing an outline of the light guide fabrication apparatus in one stage (after sealing the tube) of the electroluminescent element fabrication method of Comparative Example 1;

FIG. 8 is a sectional diagram showing an outline of the light guide fabrication apparatus in one stage (when heating) of the electroluminescent element fabrication method of Comparative Example 1; and

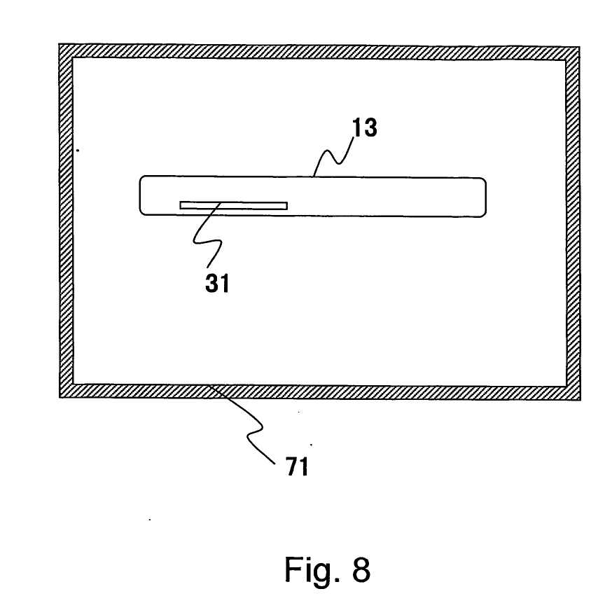

FIG. 9 is a sectional diagram showing an outline of the light guide fabrication apparatus according to an electroluminescent element fabrication method of an example.

### DESCRIPTION OF PREFERRED EMBODIMENT

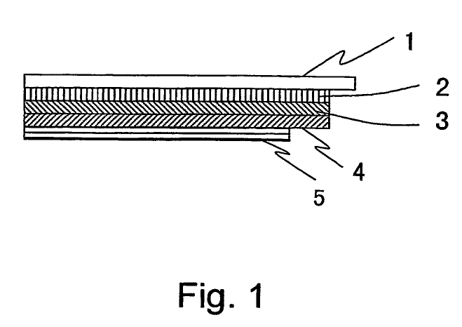

Preferred embodiments of the present invention will be described with reference to the accompanying drawings. FIG. 1 shows a sectional diagram of one embodiment of a polymer electroluminescent element of the present invention. As shown in FIG. 1, the polymer electroluminescent element of this embodiment has a hole injection layer 3 and a positive electrode 2 sequentially laminated on one side of a light-emitting layer 4 and a glass substrate 1 laminated on the other side of the positive electrode 2. Meanwhile, a negative electrode 5 is formed on the other side of the light-emitting layer 4.

For the light-emitting layer 4, a conjugation type polymer, which is provided with a charge transport ability by application of a voltage and emits light, is used. Examples of the conjugation type polymer include a π conjugated organic polymer compound, which has a chemical structure represented by the general formula —(Ar)n —and/or —(ArA)n-, wherein Ar denotes a benzene ring, a thiophene ring, a pyridine ring, a pyrrole ring or an oxadiazole ring, and A denotes a double bond, a triple bond or an NH bond, and its specific example is a polymer material containing phenylenevinylene or fluorene as a structural unit. When poly (p-phenylenevinylene) (PPV) is used as the conjugation type polymer, yellowish green light emission of 530 to 570 mm is obtained.

An example of the polymer electroluminescent element fabrication method according to this embodiment will be described. An unsubstituted π conjugated polymer, e.g., a PPV precursor (poly(p-xylenethiopheniumchloride)) solution, was applied to a glass substrate 1 on which a 500 nm thick ITO film was formed by sputtering, and then calcined to form a PPV film. Then, silver and magnesium were deposited together onto the PPV to laminate the negative electrode 5 so to produce the electroluminescent element. As a result, the PPV has an electron transport ability lower than the hole transport ability, and the luminance and luminous efficiency are insufficient. Further, because the PPV is insoluble and infusible, doping was not possible. But, it was found that a thin film of a PPV layer having penetrated PBD was obtained by placing a thin film of PPV having an electrode with a negative electrode laminated into a glass tube, placing 2-(4-biphenyl)-5-(4-tert-butylphenyl)-1,3,4-oxadiazole (PBD) as an electron transport compound in the same tube, evacuating and sealing the tube into an ampule, and thermally treating the ampule. Besides, it was found that the electroluminescent element having the negative electrode 5 laminated had remarkable electron transport and improved luminance by depositing silver and magnesium together on the thin film of PPV having a negative electrode after the penetration processing.

Details of the mechanism of penetration of a charge transport compound, a fluorescent dye and the like into the insoluble and infusible PPV are not known, but it is presumed that, because the charge transport compound and fluorescent dye are sublimated within the glass tube, the compound is resolved to a molecular level and penetrates through the fine gaps of the thin film of the PPV.

As the light-emitting layer 4 having the charge transport ability, polythiophene, polythiophenevinylene, poly(p-phenylene), poly(p-phenylacetylene) and the like can be used other than the above-described PPV.

The hole injection layer 3 is appropriately formed on the positive electrode 2 of the electroluminescent element. Examples of preferable materials for the hole injection layer include polystyrene sulufonic acid-containing poly(ethylene dioxythiophene) (PEDOT-PSS) and PTPDES represented by chemical formula I; Et-PTPDEK represented by chemical formula II and PBBA represented by chemical formula III as shown in [Formula 1] to be described later; and also copper phthalocyanine and TBPAH represented by chemical formula IV as low molecular compounds.

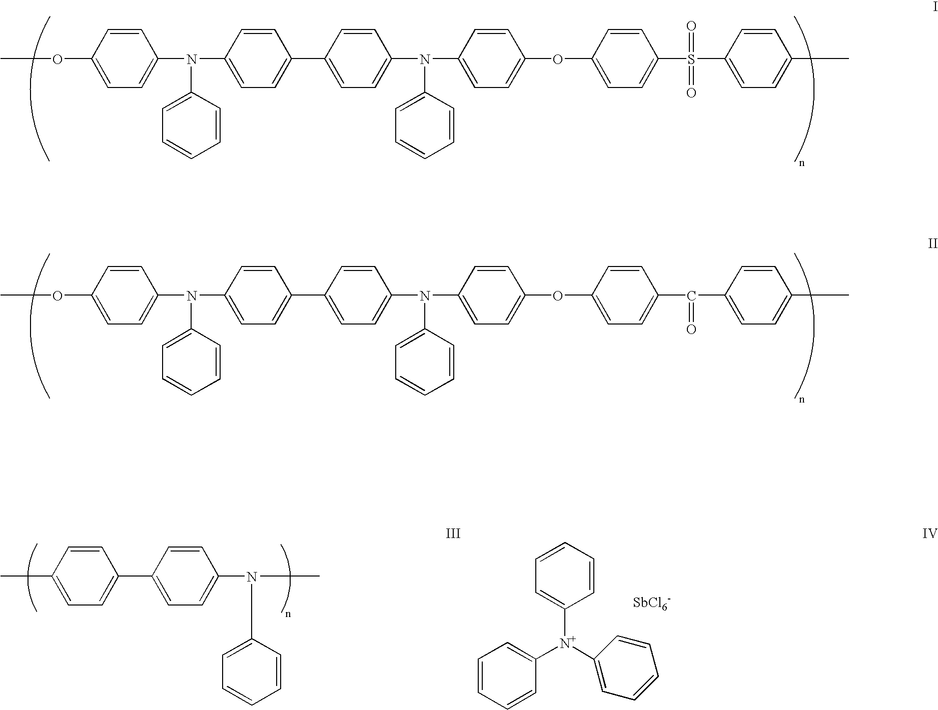

The hole transport layer is appropriately inserted between the light-emitting layer 4 and the hole injection layer 3, and polyaniline, polythiophene, polypyrrole, polythiophenevinylene and their derivatives are used. When an unsubstituted π conjugated polymer is used for the hole transport layer, the hole transport compound can be penetrated by the above-described process because it is similarly insoluble and infusible. Thus, the hole transport layer having a better efficiency can be produced. The above hole transport material can be used as a penetrating compound.

The π conjugated polymer having a light emission ability used for the hole transport layer has an electron transport ability lower than the hole transport ability, so that, as a low molecular compound which improves the electron transport ability, not only the PBD, but also the above-described electron transport material and an electron transport material having a light emission ability can be used as the penetrating compound.

According to the present invention, a luminescent color can be controlled by using not only a compound having a charge transport ability, but also a fluorescent dye for a π conjugated polymer having a light emission ability for the compound which is used for the hole transport layer. For example, when the emitted light of the PPV is green having a peak at 550 nm, a fluorescent dye having a light emission peak on a long wavelength side than 550 nm can change a fluorescent color. Possible fluorescent dyes to be used include coumarin type, quinacridone type, dicyanomethylene type, dicyanodiazepine type, benzothiazole type, perylene type, acetonitrile-triphenylamine type, Eu atom-containing complex type and azabenzoanthracene-pyran type dyes.

### EXAMPLES

Examples of the present invention will be described with reference to the accompanying drawings. It is to be understood that the invention is not restricted by the following examples.

### Example 1

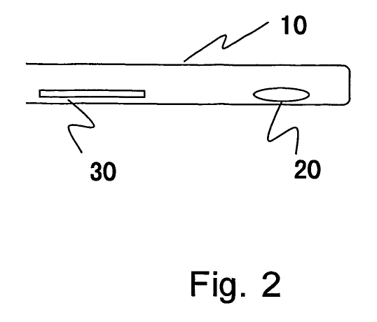

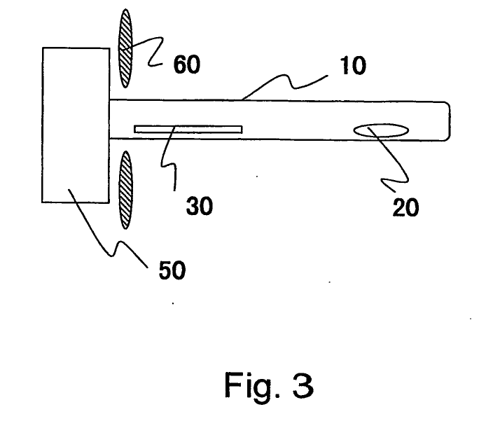

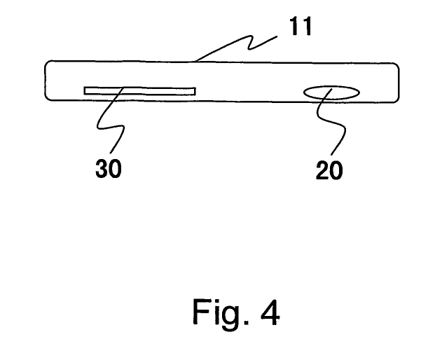

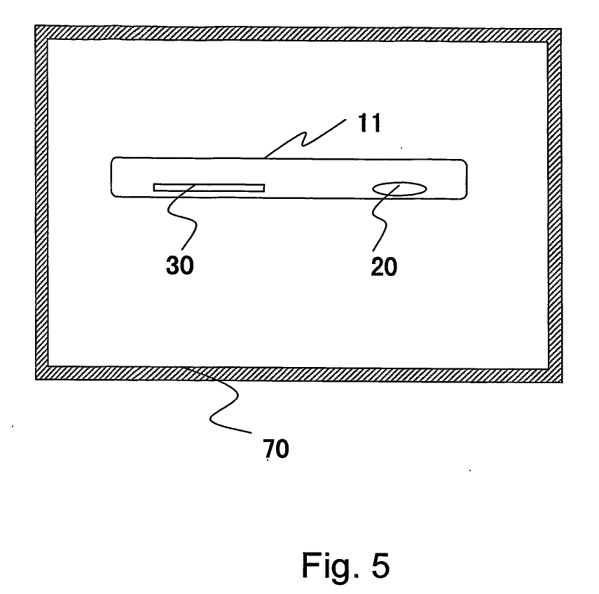

As shown in FIG. 2, for example, 100 mg of an electron transport compound 2-(4-biphenyl)-5-(4-tert-butylphenyl)-1,3,4-oxadiazole (PBD) was placed as an organic compound 20 having a vapor pressure at one end within a glass tube 10 (e.g., an outside diameter of 15 mm, an inside diameter of 12 mm) with one end closed. Then, a resin thin film 30 (1 mm thick, 8 mm wide, 40 mm long) of the PPV formed on a glass substrate having an ITO electrode was placed at the middle in the tube. The open end of the glass tube 10 was connected to an evacuation device 50 to make evacuation, and a portion close to the open end of the glass tube 10 connected to the evacuation device 50 as shown in FIG. 3 was then melted for using glass tube sealing burner 60. Thus, the organic compound 20 and the resin thin film 30 were sealed in a sealed glass tube 11 as shown in FIG. 4. After sealing, the sealed glass tube 11 was placed in a thermostatic chamber 70 as shown in FIG. 5, kept in the thermostatic chamber 70 while an inner temperature of 120° C. was maintained for one hour, and slowly cooled down to room temperature over one hour. The glass tube 11 was then cut, and the resin thin film 30 in which the organic compound 20 had penetrated and dispersed was removed. Then, silver and magnesium were deposited together to laminate a negative electrode, thereby producing an electroluminescent element. This electroluminescent element emitted yellowish green light and had the maximum luminance of 3000 cd/m² at 14V. External quantum efficiency was 3.2 lm/w.

With consideration given to the development of a display monitor, the luminance must be approximately 1000 cd or more, yet variable depending on the fineness of pixels. If the luminance is less than 1000 cd, it may not be possible to recognize an image in a room environment (under fluorescent light). When the external quantum efficiency is 1.0 lm/w or less, power consumption is large, normal batteries are consumed in just several minutes of lighting, and a heating value is so high that the element itself might be damaged. The “lm/w” used in the above and later examples denotes “lumen/watt”.

### Comparative Example 1

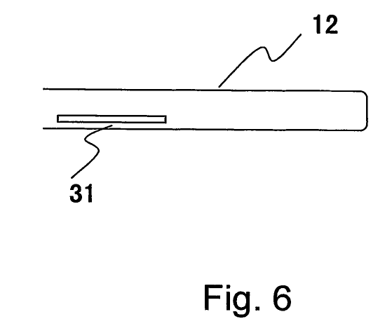

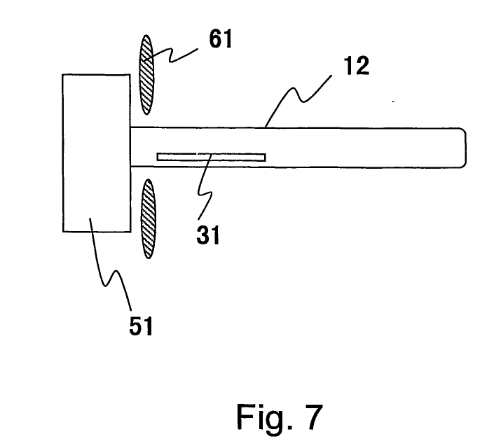

To ascertain the effect of 2-(4-biphenyl)-5-(4-tert-butylphenyl)-1,3,4-oxadiazole (PBD) of Example 1, a comparative experiment of heating a resin thin film 31 (1 mm thick, 8 mm wide, 40 mm long) of PPV formed on the glass substrate having an ITO electrode was conducted as follows. Specifically, only the resin thin film 31 of PPV formed on the glass substrate having the ITO electrode was placed in a glass tube 12 having an outside diameter of 15 mm, an inside diameter of 12 mm, a length of 200 mm, with one end closed as shown in FIG. 6. The open end of the glass tube 12 was connected to an evacuation device 51 to conduct evacuation. Then, a section of the glass tube 12 connected to the evacuation device 51 near its open end was melted and sealed by a glass tube sealing burner 61 in order to seal the resin thin film in the sealed glass tube 12 as shown in FIG. 7. The sealed glass tube 12 was placed in a thermostatic chamber 71, and the inside temperature of the thermostatic chamber 71 was maintained at 120° C. for 24 hours, and then slowly cooled to room temperature. After cooling, the glass tube 12 was cut to remove the thermally treated resin thin film 31 of PPV formed on the glass substrate having the ITO electrode. Then, silver and magnesium were deposited together to laminate a negative electrode, thereby manufacturing an electroluminescent element. The manufactured electroluminescent element emitted yellowish green light and had maximum luminance of 20 cd/m² at 14V, and the external quantum efficiency was 0.7 lm/w.

### Comparative Example 2

The resin thin film of PPV formed on the glass substrate having an ITO electrode was sealed in the tube, heated and slowly cooled in the same manner as in Example 1, with the exception that perfluorooctane was used instead of the PBD. The obtained resin thin film of PPV was measured for ultraviolet, visible and infrared absorption spectra, and no absorption derived from perfluorooctane could be recognized. These results are evidence that the perfluorooctane did not have an affinity for the resin thin film of PPV and that, therefore, penetration and dispersion into the plate of the resin thin film did not occur.

It was found from Example 1 and Comparative Examples 1 and 2 that, when the organic compound was vaporized by heating in the decompressed sealed glass tube, the glass tube was filled with vapor, and when the vapor was kept in a heated state without cooling and the resin thin film having the affinity for the organic compound was placed in the vapor, organic molecules, which could develop desired functions, were dispersed within the resin thin film.

### Example 2

As shown in FIG. 2, as the organic compound 20 having a vapor pressure, 100 mg of an orange color fluorescent dye, 4-(dicyanomethyl)-2-methyl-6-(4-dimethylaminostyryl)-4-H-pyran (DCM), was placed at one end within the glass tube 10 having an outside diameter of 15 mm and an inside diameter of 12 mm, with one end closed. Then, a resin thin film PPV 30 (1 mm thick, 8 mm wide, 40 mm long) of the PPV formed on a glass substrate having an ITO electrode was placed in the middle of the tube. The open end of the glass tube 10 was connected to the evacuation device 50 and the tube was evacuated. After that, a portion close to the open end of the glass tube 10 connected to the evacuation device 50 as shown in FIG. 3 was melted for sealing by the glass tube sealing burner 60. Thus, the organic compound 20 and the resin thin film 30 were sealed in the sealed glass tube 11 as shown in FIG. 4. After sealing, the sealed glass tube 11 was placed in the thermostatic chamber 70 as shown in FIG. 5, kept in the thermostatic chamber 70 having the inside temperature of 120° C. for one hour, and slowly cooled down to room temperature over one hour. After cooling, the glass tube 11 was cut, and the PPV having the organic compound 20 penetrated and dispersed in it was removed. Then, silver and magnesium were deposited together to laminate a negative electrode, thereby producing an electroluminescent element. The electroluminescent element emitted orange-color light and had the maximum luminance of 2000 cd/m² at 14V. External quantum efficiency was 4.1 lm/w.

### Example 3

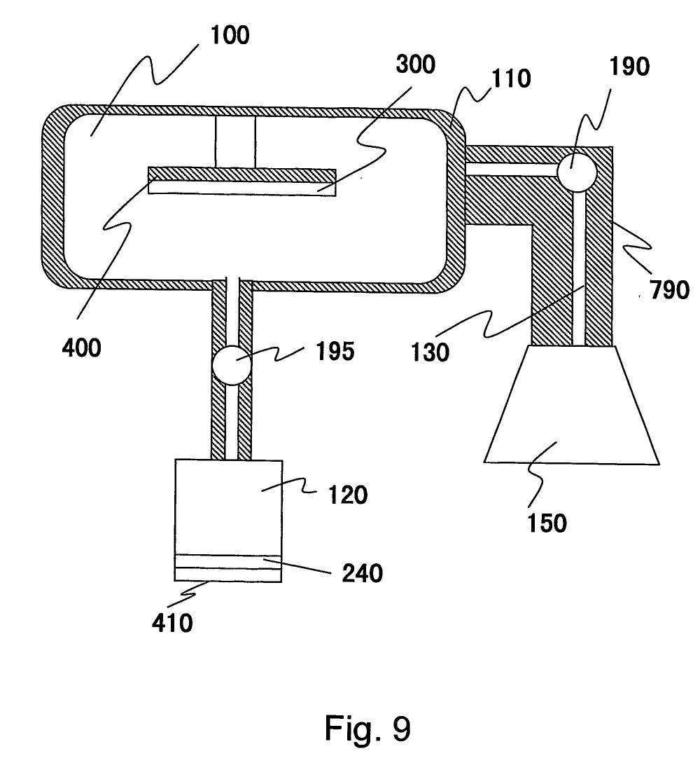

FIG. 9 is a sectional diagram showing a schematic structure of the electroluminescent element fabrication apparatus used in this example. A resin thin film 300 having PPV, which was formed by forming a film of PEDOT-PSS on a glass substrate having the ITO, applying a poly (p-xylenethiopheniumchloride) solution onto it and calcining, was used. Meanwhile, a sublimation source 240 having PBT disposed (5 mm thick, 10 mm wide, 400 mm long) was produced. The resin thin film 300 of the PEDOT-PSS/PPV having the ITO was placed in an airtight container 110, and the sublimation source 240 was disposed in another air tight container 120. The two airtight containers 110, 120 were mutually connected through a pipe and a valve 195. The airtight container 110 in which the resin thin film 300 of the PEDOT-PSS/PPV having the ITO was disposed had a stainless steel or aluminum outer wall and a structure (not shown) which could be divided into upper and lower sections for loading/unloading of the resin thin film 300.

The airtight container 110 had an interior 100 connected to an evacuation system 150 through a vacuum valve 190 and an evacuation piping system 130 and was exhausted so that the airtight container 110 had an inside pressure of 10⁻⁴ Pascal or less at room temperature, and the vacuum valve 190 was closed. Thus, the airtight container 110 was sealed airtight.

As heating means, a sublimation source substrate heater 410, a resin thin film rod-shape heater 400, and a vacuum valve heater 790 which are formed of aluminum having, for example, a sheath electric heating wire of vacuum specifications embedded can be used. The interior 100 of the airtight container 110 and the vacuum valve 190 can be heated uniformly by a heater made of a material having a high heat transfer property and disposed without leaving any gap.

In this example, the interior 100 of the airtight container 110 was decompressed, and heat was applied using a sublimation source substrate heater 410 as described above, to control the temperature of the whole to a preset temperature (e.g., 150° C. when PBD was used as the vaporization source 240). The airtight container 120 having the vaporization source sealed airtight was also heated in the same way to a temperature (155° C., in this case) higher than the preset temperature of the airtight container 110 which had the resin thin film 300 of the PEDOT-PSS/PPV having the ITO disposed therein. Then, the valve 195 connecting the two airtight containers 110 and 120 was opened, and the set temperatures inside the individual containers was maintained for 30 minutes. The temperatures inside the airtight containers 110 and 120 were then slowly lowered to 25° C. Then, the interior 100 of the airtight container 110 was restored to have the atmosphere, and the resin thin film 300 of the PEDOT-PSS/PPV in which the PBD penetrated and dispersed was removed. Silver and magnesium were deposited together to laminate a negative electrode, thereby producing an electroluminescent element. This electroluminescent element emitted orange-color light and had the maximum luminance of 4500 cd/m² at 14V. External quantum efficiency was 4.8 lm/w.

As described above, the electroluminescent element of the present invention is completely and reliably free from impurities within the π conjugated organic polymer compound because a sublimation or volatile charge transport organic compound and a fluorescent dye are used instead of processing such as doping and contacted as gas molecules to cause penetration so to be contained in the π conjugated organic polymer compound. Additionally, because in the electroluminescent element manufacturing method of the present invention the sublimation or volatile charge transport organic compound and the fluorescent dye can be contained in the π conjugated organic polymer compound by contacting and penetrating as gas molecules, there is no possibility that the impurities will be contained in the π conjugated organic polymer compound. Therefore, an organic film formed of the π conjugated organic polymer compound free from a possibility of containing impurities can be produced. As a result, an electroluminescent element, which has a high luminous efficiency and capable of illuminating light of variable or changing colors, can be produced efficiently.

### INDUSTRIAL APPLICABILITY

As described above in detail, the present invention provides an electroluminescent element which has a high luminous efficiency and which can change a luminescent color.

1. An organic electroluminescent element containing a π conjugated organic polymer compound, comprising a functional layer which is formed by causing gas molecules of at least one type of compound selected from the group consisting of dyes and charge transport materials to contact and penetrate the π conjugated organic polymer compound.

2. An organic electroluminescent element containing a π conjugated organic polymer compound, comprising a light-emitting layer which is formed by causing gas molecules of at least one type of compound selected from the group consisting of dyes and charge transport materials to contact and penetrate the π conjugated organic polymer compound.

3. An organic electroluminescent element containing a π conjugated organic polymer compound, comprising a charge transport layer which is formed by causing gas molecules of at least one type of compound selected from the group consisting of dyes and charge transport materials to contact and penetrate the π conjugated organic polymer compound.

4. An organic electroluminescent element containing a π conjugated organic polymer compound, comprising a light-emitting layer and a charge transport layer which are formed by causing gas molecules of at least one type of compound selected from the group consisting of dyes and charge transport materials to contact and penetrate the π conjugated organic polymer compound.

5. A method for manufacturing an organic electroluminescent element, comprising causing gas molecules of at least one type of compound selected from the group consisting of dyes and charge transport materials to contact and penetrate at least a π conjugated organic polymer compound.

6. The organic electroluminescent element according to claim 1, wherein the π conjugated organic polymer compound has a chemical structure represented by a general formula —(Ar)n- and/or —(ArA)n-, where Ar represents a benzene ring, a thiophene ring, a pyridine ring, a pyrrole ring or an oxadiazole ring and A represents a double bond, a triple bond or an NH bond.

7. The organic electroluminescent element according to claim 1, wherein the π conjugated organic polymer compound is at least one type selected from the group consisting of poly(p-phenylenevinylene), polythiophene, polythiophenevinylene, poly(p-phenylene) and poly(p-phenylacetylene).

8. The organic electroluminescent element according to claim 1, wherein the dye is a fluorescent dye.

9. The organic electroluminescent element according to claim 8, wherein the fluorescent dye is at least one type of dye selected from the group consisting of a coumarin type dye, a quinacridone type dye, a dicyanomethylene type dye, a dicyanoazepine, a benzothiazole type dye, a perylene type dye, an acetonitrile-triphenylamine type dye, an Eu atom-containing complex type dye and an azabenzoanthracene-pyran type dye.

10. The organic electroluminescent element according to claim 1, wherein the charge transport compound is at least one type of compound selected from the group consisting of a hole transport material which transports a positive (+) charge, an electron transport material which transports a negative (−) charge, and an electron transport compound having a light emission ability.

11. The organic electroluminescent element according to claim 10, wherein the hole transport material is at least one type of hole transport material selected from the group consisting of low molecular compounds having a carbazole ring, a thiophene ring, triphenylamine, triphenylmethane or distilbene structure, and compounds having the low molecular compounds bonded by a diazo or triazo group.

12. The organic electroluminescent element according to claim 10, wherein the electron transport material is at least one type of electron transport material selected from the group consisting of compounds having an oxadiazole ring, a triazole ring, a quinone ring, an imidazole ring, a flavone ring, a thiazole ring, a benzimidazole ring, a quinoline ring, a quinozaline ring or a pyrazine ring, and compounds having a nitro group or a cyano group introduced into the former compounds.

13. The organic electroluminescent element according to claim 10, wherein the electron transport compound having a light emission ability is at least one type selected from the group consisting of aluminum, zinc, beryllium, europium and erbium complexes having a benzooxadiazole ring, a quinolyl ring, a benzoquinolyl ring, a benzothiazole ring or a hydoxyflavone ring in a ligand.
